(19) United States
(12) Patent Application Publication
(10) Pub. No.: US 2008/0121902 A1
(43) Pub. Date: May 29, 2008

(54) Small footprint high power light emitting package with plurality of light emitting diode chips

(75) Inventors: Michael Sackrison, Bethlehem, PA (US); Xiang Gao, Edison, NJ (US); Srinath K. Aanegola, Broadview Heights, OH (US); Hari S. Venugopalan, Somerset, NJ (US)

Correspondence Address: FAY SHARPE LLP, 1100 SUPERIOR AVENUE, SEVENTH FLOOR, CLEVELAND, OH, 44114, US

(73) Assignee: GELcore LLC

(21) Appl. No.: 11/517,053

(22) Filed: Sep. 7, 2006

(51) Int. Cl. H01L 33/00

(52) U.S. Cl. 257/89; 257/E33.058

(57) ABSTRACT

A light emitting package includes a support (12, 112, 212) defining a support surface (14). A first light emitting diode chip (20, 120, 220) is secured to the supporting surface and is configured to emit light having a first spectral distribution. A second light emitting diode chip (22, 122, 123, 222) is secured to the first light emitting diode chip. The second light emitting diode chip is configured to emit light having a second spectral distribution different from the first spectral distribution. Optionally, a third light emitting diode chip (223) is disposed on the second light emitting diode chip (222).

### BACKGROUND

The following relates to the lighting arts. It especially relates to light emitting packages for illumination. However, the following will also find application in conjunction with other light emitting packages, in applications benefiting from improved light emitting packages, and so forth.

Light emitting diode chips are used for indicator lights, as light sources for optical scanners, and so forth. Light emitting diode chips are also used for illumination. However, in illumination applications the relatively low light output of light emitting diode chips is problematic. Additionally, a typical light emitting diode chip emits light over a relatively narrow wavelength range, whereas white illumination is preferred for some applications.

To address these problems, it is known to use a light emitting package that employs a plurality of light emitting diode chips. Using several chips provides higher light output, and if the colors of the chips are suitably selected (for example, by selecting red, green, and blue chips or a similar combination of saturated colors) the light output can approximate white light. Alternatively, it is known to employ light emitting diode chips that emit in the blue, violet, or ultraviolet range, and to coat such chips with a suitable phosphor blend to approximate white light. The output can be substantially completely converted light (e.g., ˜100% conversion efficiency with the phosphor producing approximately white light) or can be a blend of direct chip emission and converted phosphor emission (e.g., blue direct chip emission and yellowish converted phosphor emission that blend to approximate white light).

However, the design of a light emitting package employing a plurality of light emitting diode chips presents certain difficulties. The use of multiple chips spreads out the area of light emission, which can be problematic in applications in which a small source is desired. The laterally spread-out light emission is difficult to focus or otherwise manipulate using diffractive or refractive optical elements. If light from light emitting chips emitting light at different wavelengths are blended to approximate white light, then a large footprint for the light emitting package can also be problematic by reducing the effectiveness of the light blending. Moreover, in some applications it may be desired to use a plurality of such light emitting packages to produce larger total light output—again, a large package footprint is problematic for achieving close spacing in an array or other aggregate of light emitting packages.

### BRIEF SUMMARY

Example light emitting packages are disclosed. In one disclosed example light emitting package, a support defines a support surface. A first light emitting diode chip is secured to the supporting surface and is configured to emit light having a first spectral distribution. A second light emitting diode chip is secured to the first light emitting diode chip. The second light emitting diode chip is configured to emit light having a second spectral distribution different from the first spectral distribution.

### BRIEF DESCRIPTION OF THE DRAWINGS

The invention may take form in various components and arrangements of components, and in various process operations and arrangements of process operations. The drawings are only for purposes of illustrating example embodiments and are not to be construed as limiting.

FIGS. 1A and 1B show top and side sectional views, respectively, of a light emitting package. FIG. 1A includes an indication of the section line S-S along which the section of FIG. 1B is taken.

FIGS. 2A and 2B show top and side views, respectively, of a light emitting package. FIG. 2A includes an indication of the section line S-S along which the section of FIG. 2B is taken.

FIG. 3 diagrammatically shows another arrangement of stacked light emitting diode chips, in which a bottommost first chip supports two different types of additional light emitting diode chips disposed thereon.

FIG. 4 diagrammatically shows another arrangement of stacked light emitting diode chips, in which a bottommost first chip has a second light emitting diode chip disposed thereon, and a third light emitting diode chip is disposed on the second light emitting diode chip.

### DETAILED DESCRIPTION OF PREFERRED EMBODIMENTS

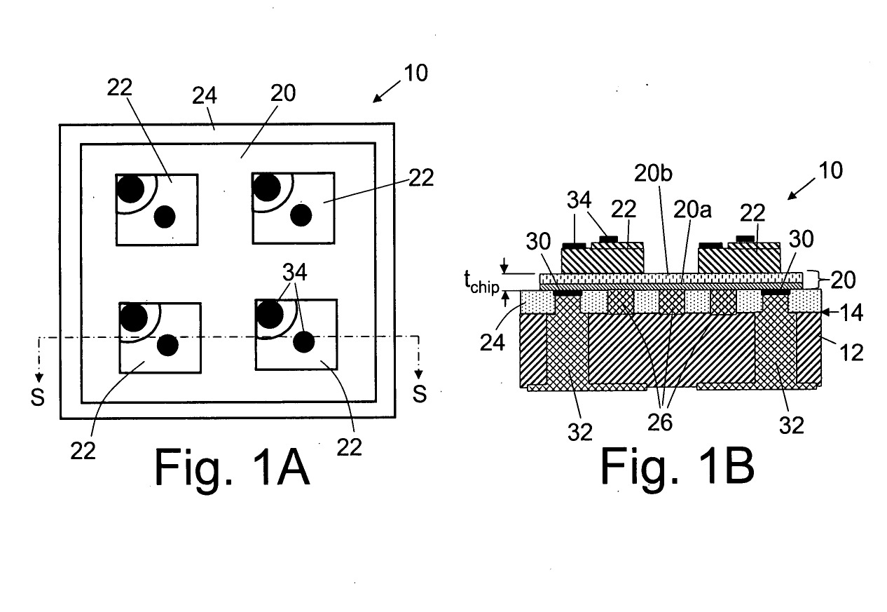

With reference to FIGS. 1A and 1B, a light emitting package 10 includes a support 12 defining a generally planar surface 14, a first light emitting diode chip 20 disposed on the generally planar surface 14, and one or more additional light emitting diode chips 22 disposed on the first light emitting diode chip 20. In the illustrated embodiment, the first light emitting diode chip 20 is a thin light emitting diode chip having a thickness t_{chip} in a direction transverse to the supporting surface 14 of less than 30 microns, and more preferably each having a thickness t_{chip} of less than 10 microns, and still more preferably each having a thickness t_{chip} of less than 5 microns. The use of a thin light emitting diode chip as the bottommost (first) light emitting diode chip 20 has advantages such as improved thermal conduction of heat generated in the chips 20, 22 to the support 12 (that is, better heat sinking), and more efficient and more controlled light extraction from the first chip 20 due to reduced side emission. However, it is also contemplated to use a thicker first light emitting diode chip, such as a chip including a substrate.

The term “chip” as used herein is intended to denote a physically discrete component configured to be electrically energized to emit light. It is contemplated for a chip to be a physically discrete component that includes a plurality of monolithically integrated light emitting structures, such as a plurality of light emitting mesas.

The light emitting diode chips 20, 22 can be made of various materials, such as group IV semiconductors, group III-V semiconductors, group II-VI semiconductors, organic semiconductors, polymers, or so forth. In some embodiments, the first light emitting diode chip 20, 22 is a thin chip that includes epitaxial layers but does not include a lattice-matched substrate. Such a chip can be fabricated by: (i) depositing the epitaxial layers on a lattice-matched substrate epitaxially using molecular beam epitaxy, chemical vapor deposition, or another epitaxial growth or deposition technique; (ii) bonding the epitaxial layers to the surface 14 (e.g., using flip chip bonding in which electrodes formed on the epitaxial layers are electrically bonded to electrically conductive areas on the surface 14); and (iii) removing the lattice-matched substrate. To provide sufficient structural support for the epitaxial layers during and after liftoff, a suitable underfill material 24 (such as an epoxy or silicone underfill material) is optionally disposed between the epitaxial layers of the first light emitting diode chip 20 and the generally planar surface 14. In some embodiments, the first chip 20 includes group III-nitride epitaxial layers deposited on lattice matched sapphire substrates, and some suitable processes for performing the substrate removal operation (iii) include laser lift-off processes as described, for example, in Miskys et al., “Freestanding GaN-Substrates and Devices”, Phys. Stat. Sol. (c) 0, No. 6, pp. 1627-50 (2003) which is incorporated by reference herein in its entirety, and Cheung et al., U.S. Pat. No. 6,071,795 which is incorporated by reference herein in its entirety.

The term “lattice matched substrate” as used herein is intended to encompass any substrate that is capable of supporting epitaxial growth of the epitaxial layers. As such, the term “lattice matched substrate” as used herein is intended to encompass substrates having a small lattice mismatch respective to the epitaxial layers (e.g., a mismatch of typically less than 8%, and more preferably less than 4%, still more preferably less than 2%, and still more preferably less than 1%), and is further intended to encompass substrates having a different crystallographic pattern or orientation as compared with the epitaxial layers, such as cubic group III-nitride epitaxial layers on a (0001) hexagonal sapphire substrate.

Substrate lift-off processes are not the only way the thin light emitting diode chip 20 can be manufactured. In other embodiments, the substrate is thinned, rather than wholly removed. Thinning of the substrate can be accomplished, for example, by chemical etching, mechanical polishing, chemical-mechanical polishing, laser ablation, or so forth. In these embodiments, the thin light emitting chip 20 includes the epitaxial layers and a portion of the lattice matched substrate that remains after the substrate thinning. In some approaches, such a thinning process is continued until the substrate is completely removed, such that the thin light emitting chip 20 includes no remaining substrate. The described approaches for fabricating and bonding the thin light emitting diode chip 20 are examples, and other techniques can be employed. As noted previously, in some embodiments the first light emitting diode chip 20 is not thin, that is, has a thickness of at least 30 microns. For example, the first light emitting diode chip may include group III-nitride epitaxial layers disposed on a lattice matched sapphire or silicon carbide substrate.

A consideration is providing adequate heat-sinking for the thin light emitting diode chip 20 and the additional light emitting diode chips 22 attached to the first chip 20. In some embodiments, these chips 20, 22 are high-power chips that each have operative input power greater than or about 1 watt. Such high-power chips advantageously provide substantial light output per chip, but also typically produce substantial amounts of heat. Making the first chip 20 a thin chip advantageously reduces thermal path length through the first chip 20. On the other hand, if the first chip 20 is a thick chip, for example including a lattice matched substrate having thickness of at least 30 microns, then the substrate should be sufficiently thermally conductive to conduct heat from the additional light emitting diode chips 22 to the support 12. In some embodiments, the optional underfill material 24 is a thermally conductive underfill material that provides enhanced thermal conduction from the first light emitting diode chip 20 to the supporting surface 14. Optionally, thermally conductive paths 26 provide thermal conduction pathways from the thin light emitting diode chip 20 to the supporting surface 14. These are illustrative heat-sinking approaches, and other heat-sinking mechanisms can be additionally or alternatively employed. For example, in some embodiments the support 12 is a metal-core printed circuit board, or includes thermal radiation fins, or includes other materials or structure that provides enhanced heat capacity and/or heat dissipation.

In the illustrated embodiment, the first light emitting diode chip 20 is flip chip bonded such that electrodes 30 of the first chip 20 electrically contact electrical feedthroughs 32 that pass through the support 12. This backside electrical power input to the first chip 20 via the feedthroughs 32. In other embodiments, the first chip 20 may contact printed circuitry disposed on the frontside surface 14 of the support 12. In yet other embodiments, the first chip 20 may have exposed front side contacts that are energized via wire bonds.

In some embodiments, the first light emitting diode chip 20 includes a semiconductor based structure 20a (such as group III-nitride epitaxial layers, optionally further including a lattice matched substrate, such optional lattice matched substrate being optionally thinned) configured to emit excitation light, and a phosphor containing material 20b disposed on the semiconductor based structure 20a and configured to convert at least a portion of the excitation light to converted light. The group III-nitride epitaxial layers or other semiconductor based structure 20a is configured to operate in conjunction with the phosphor containing material 20b disposed above (as illustrated) or below the group III-nitride epitaxial layers 20a to produce a desired light output. In one example embodiment, group III-nitride epitaxial layers 20a output ultraviolet light, and the phosphor containing material 20b includes dispersed phosphor particles that down-convert the ultraviolet light to a desired light output, such as green light. In some embodiments, the phosphor containing material 20b may be omitted and the direct light generated by the group III-nitride epitaxial layers 20a utilized. In general, the output of the first light emitting diode chip 20 emits light having a first spectral distribution, which may for example be direct light generated by epitaxial layers, or down-converted light generated by a phosphor excited by light generated by epitaxial layers, or a blending of down-converted light generated by a phosphor and direct light generated by epitaxial layers, or so forth. In one specific example embodiment, the phosphor containing material 20b includes a green phosphor that emits green light when excited by ultraviolet radiation generated by group III-nitride epitaxial layers 20a.

In some embodiments, the underfill material 24 at least contributes to the securing of the first light emitting diode chip 20 to the supporting surface 14. The securing may additionally or alternatively be provided by other mechanisms, such as by flip chip bonds connecting the electrodes 30 of the thin light emitting diode chip 20 to the electrical feedthroughs 32, by bonds of the thin light emitting diode chip 20 to the thermal bumps or paths 26, or by various combinations thereof.

The light emitting package 10 further includes the plurality of additional light emitting diode chips 22 (an example four additional chips 22 in the illustrated embodiment) each emitting light having a second spectral distribution that is different from the first spectral distribution of the light emitted by the thin light emitting diode chip 20. The light emitting diode chips 22 are disposed on the thin light emitting diode chip 20. In the illustrated embodiment, the phosphor containing material 20b of the thin light emitting diode chip 20 includes an adhesive binder material that, in addition to providing a matrix for supporting dispersed phosphor particles, also at least contributes to the securing of the additional light emitting diode chips 22 to the thin light emitting diode chip 20. In other embodiments, a dedicated adhesive or bonding bumps such as solder bumps, thermocompressive bumps, thermosonic bumps, or the like (not shown) at least contribute to bonding the additional light emitting diode chips 22 to the thin light emitting diode chip 20.

The attachment of the light emitting diode chips 22 to the bottommost (first) light emitting diode chip 20 should be thermally conductive to promote heat transfer from the light emitting diode chips 22 to the bottommost light emitting diode chip 20. Heat flows through the bottommost light emitting diode chip 20 to the underlying support 12. In the illustrated embodiment, the bottommost light emitting diode chip 20 is a thin light emitting diode chip in which the lattice matched substrate used for epitaxial growth has been removed, which promotes thermal conduction through the chip 20 in the direction transverse to the supporting surface 14. More generally, such thermal conduction through the bottommost light emitting diode chip 20 is promoted by having the thickness t_{chip} in the direction transverse to the supporting surface 14 be less than 30 microns, and more preferably less than 10 microns, and still more preferably less than 5 microns. However, if the lattice matched substrate used in growing the epitaxial layers of the bottommost chip is sufficiently thermally conductive, it is contemplated to retain the thermally conductive substrate, in which case the bottommost light emitting diode chip may have a thickness in the direction transverse to the supporting surface 14 of greater than 30 microns.

In the illustrated embodiment, the light emitting diode chips 22 have a non-inverted configuration, in which each light emitting diode chip 22 includes top-side bonding bumps 34 for wire bonding. The illustrated light emitting diode chips 22 are thin light emitting diode chips, having a thickness transverse to the supporting surface 14 that is less than 30 microns, and more preferably less than 10 microns, and still more preferably less than 5 microns. Using thin light emitting diode chips 22 enables relatively close spacing of the chips 22 on the bottommost chip 20 while substantially suppressing side emission losses. For example, a minimum separation between the light emitting diode chips 22 disposed on the bottommost chip 20 can be less than 500 microns, or less than 200 microns, or less than 100 microns. However, it is also contemplated to use one or more thicker chips disposed on the bottommost light emitting diode chip 20.

The number of upper light emitting diode chips can be one, two, three, four (e.g., as in the illustrated four chips 22), or more. In the illustrated embodiment, the four light emitting diode chips 22 have a combined area that is less than an area of the bottommost light emitting diode chip 20, and are arranged on the bottommost light emitting diode chip 20 in non-overlapping fashion. This arrangement promotes light extraction from both the upper light emitting diode chips 22 and the bottommost light emitting diode chip 20. In some embodiments, the second spectral distribution of the upper light emitting diode chips 22 has a peak wavelength that is shorter than a peak wavelength of the first spectral distribution of the bottommost light emitting diode chip 20. This arrangement is typically advantageous because semiconductor materials that produce a shorter wavelength emission are typically substantially optically transparent at longer wavelengths. Accordingly, by placing the shorter wavelength chips 22 on top of the bottommost longer wavelength chip 20, the longer wavelength emission from the chip 20 can pass through the shorter wavelength upper chips 22 and be extracted. If the upper wavelength chips are sufficiently transparent to the first spectral distribution generated by the bottommost chip, then it is contemplated for the upper chip (or plurality of upper chips) to have substantially the same area as the bottommost chip and to substantially “cover up” the bottommost chip. Where a single upper chip is used, side emission losses may be of less concern (since there are no neighboring chips) and so a thicker upper chip may be used without substantially enhancing side emission losses.

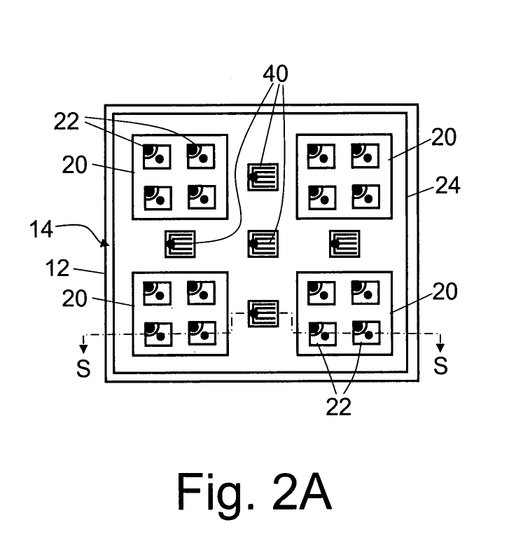

With reference to FIGS. 2A and 2B, the arrangement illustrated in FIGS. 1A and 1B can be combined with other light emitting diode chips 40 disposed on the generally planar supporting surface 14 of the support 12. In the illustrated embodiment, the light emitting diode chips 40 have a vertical structure, in which a lower bonding bump 42 is bonded to a feedthrough 44 and an upper bonding bump 46 is configured for wire bonding. The light emitting diode chips 40 suitably emit light having a third spectral distribution different from the first and second spectral distributions. For example, in one suitable embodiment for generating white light, the bottommost light emitting chip 20 emits the first spectral distribution corresponding to green light (for example, using epitaxial layers 20a generating ultraviolet radiation that is converted to green light by green phosphor contained in the phosphor containing material 20b), the second spectral distribution generated by the upper light emitting diode chips 22 corresponds to blue light, and the third spectral distribution generated by the light emitting diode chips 40 corresponds to red light. As is known in the art, a combination of red, green, and blue light of suitable relative intensities approximates white light.

In the embodiment illustrated in FIGS. 2A and 2B, there are four thin bottommost light emitting diode chips 20 disposed on the supporting surface 14, and each bottommost chip 20 supports four upper light emitting diode chips 22. Additionally, there are five of the additional light emitting diode chips 40 disposed on areas of the supporting surface 14 in-between the bottommost light emitting diode chips 20. This arrangement is an example, and other arrangements can be used.

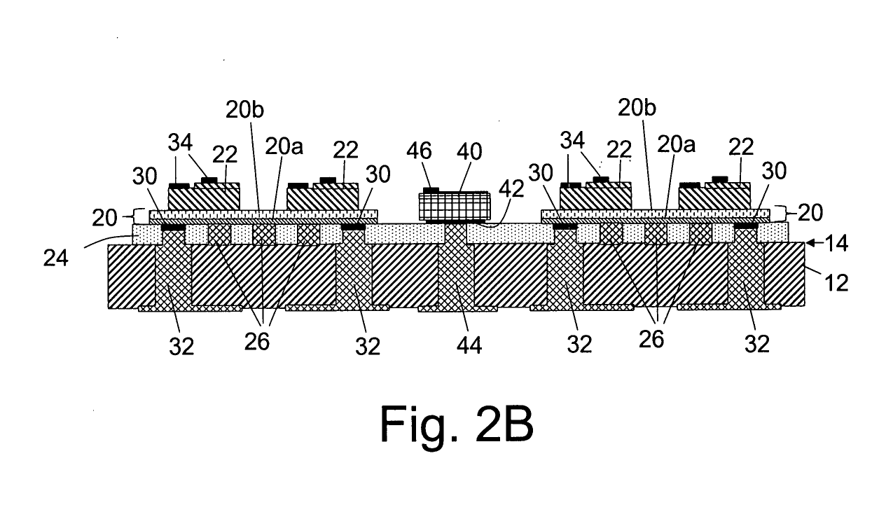

With reference to FIG. 3, more than one different type of chip can be stacked on the first chip. In FIG. 3, a support 112 supports a first light emitting diode chip 120 that is optionally a thin chip having a thickness of less than 30 microns, and more preferably less than 10 microns, and still more preferably less than 5 microns. Additional light emitting diode chips 122, 123 of different types are disposed on the first chip 120. Additional chips 122, 123 are also optionally thin chips, and are preferably translucent or transparent respective to light generated by the underlying first chip 120. The different types of chips 120, 122, 123 each emit different light spectra. Dielectric layers 126 provide electrical isolation between first chip 120 and each of additional chips 122, 123. The dielectric layers 126 may adhere one or both of the additional chips 122, 123 to chip 120, or alternatively a separate bonding adhesive may be provided.

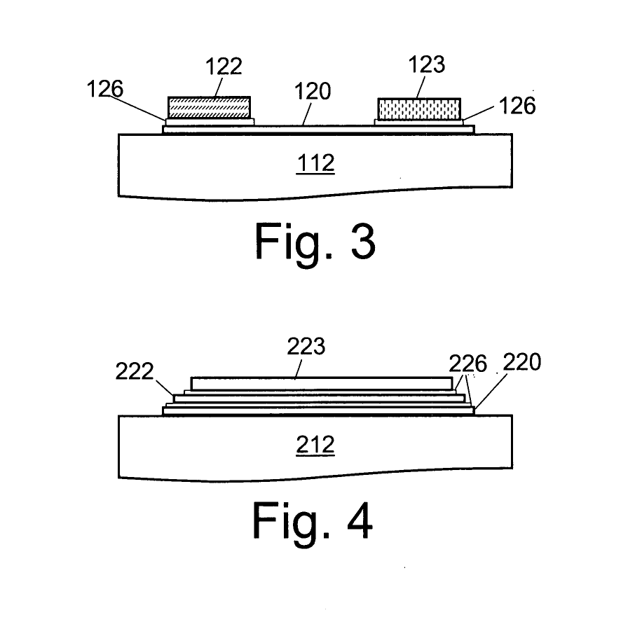

With reference to FIG. 4, it is also contemplated to stack more than two layers of light emitting diode chips. A support 212 supports a first light emitting diode chip 220, which in the illustrated embodiment is a thin chip. A second light emitting chip 222, which is also preferably a thin chip, is bonded to the first chip 220. A third light emitting diode chip 223 is bonded to the second light emitting diode chip 222. Here, the chip 223 should be translucent or transparent for light produced by underlying chips 220, 222, while chip 222 should be translucent or transparent for light produced by underlying chip 220. For example, the light emitting chip 220 may emit red light, the light emitting chip 222 green light, and the light emitting chip 223 blue light so as to generate composite white light. To promote efficient heat sinking, it is advantageous for each of chips 220, 222, and optionally also chip 223, to be thin chips having a thickness of less than 30 microns, and more preferably less than 10 microns, and still more preferably less than 5 microns.

Various arrangements can be used for electrically contacting the chips 220, 222, 223. In one approach, the chip 220 is flip chip bonded to the support 212 (similarly to the flip chip bonding of chip 20 to support 12 as seen in FIG. 1B) and uppermost chip 223 is suitably contacted using front side electrodes and wire bonding. The middle chip 222 can be contacted by placing electrodes at exposed edges of the chip 222, assuming that chip 223 has smaller area than chip 222 (as illustrated). Dielectric layers 226 provide electrical isolation between first chip 220 and middle chip 222, and between the middle chip 222 and the top chip 223. The dielectric layers 226 may adhere topmost chip 222 to middle chip 222 and middle chip 222 to bottommost chip 220, or alternatively a separate bonding adhesive may be provided. One or both of the dielectric layers 226 may also contain a wavelength-converting phosphor. The first, second, and third light emitting diode chips 220, 222, 223 each emit light having different spectral distributions.

Examples of two-chip and three-chip stacks have been illustrated. It will be appreciated that such stacking can be extended to a four- or more chip stack.

The invention has been described with reference to the preferred embodiments. Obviously, modifications and alterations will occur to others upon reading and understanding the preceding detailed description. It is intended that the invention be construed as including all such modifications and alterations insofar as they come within the scope of the appended claims or the equivalents thereof.

The appended claims follow:

1. (canceled)

2. A light emitting package comprising:
a support defining a support surface;
a thin light emitting diode chip comprising a physically discrete component secured to the supporting surface and configured to he electrically energized to emit light having a first spectral distribution, the thin light emitting diode chip having a thickness in a direction transverse to the supporting surface that is less than or about 30 microns; and
a second light emitting diode chip comprising a physically discrete component secured to the thin light emitting diode chip, the second light emitting diode chip being configured to be electrically energized to emit light having a second spectral distribution different from the first spectral distribution.

3. The light emitting package as set forth in claim 2, wherein the thin light emitting diode chip has a thickness in the direction transverse to the supporting surface that is less than or about 10 microns.

4. The light emitting package as set forth in claim 2, wherein the thin light emitting diode chip has a thickness in the direction transverse to the supporting surface that is less than or about 5 microns.

5. The light emitting package as set forth in claim 2, further comprising:
underfill material at least contributing to the securing of the thin light emitting diode chip to the supporting surface.

6. The light emitting package as set forth in claim 5, wherein the underfill material is a thermally conductive material that at least contributes to heat transfer from the thin and second light emitting diode chips to the support.

7. The light emitting package as set forth in claim 2, further comprising:
thermally conductive bumps thermally connecting the thin light emitting diode chip and the support.

8. The light emitting package as set forth in claim 2, further comprising:
a third light emitting diode chip secured to the thin light emitting diode chip, each of the second light emitting diode chip and the third light emitting diode chip being configured to emit light having the second spectral distribution different from the first spectral distribution.

9. The light emitting package as set forth in claim 8, wherein the second light emitting diode chip and the third light emitting diode chip have a combined area that is less than an area of the thin light emitting diode chip.

10. The light emitting package as set forth in claim 2, wherein the second spectral distribution has a peak wavelength that is shorter than a peak wavelength of the first spectral distribution.

11. The light emitting package as set forth in claim 2, wherein the thin light emitting diode chip comprises a plurality of group III-nitride epitaxial layers.

12. A light emitting package comprising:
a support defining a support surface;
a first light emitting diode chip secured to the supporting surface and configured to emit light having a first spectral distribution, the first light emitting diode chip comprising a plurality of semiconductor layers and a phosphor containing material disposed on the plurality of semiconductor layers; and
a second light emitting diode chip secured to the first light emitting diode chip, the second light emitting diode chip being configured to emit light having a second spectral distribution different from the first spectral distribution, the phosphor containing material of the first light emitting diode chip at least contributing to the securing of the second light emitting diode chip to the first light emitting diode chip.

13. The light emitting package as set forth in claim 12, wherein the first light emitting diode chip does not include a lattice-matched substrate.

14. The light emitting package as set forth in claim 16, wherein the first spectral distribution corresponds to green light, and the second spectral distribution corresponds to blue light, the light emitting package further comprising:
a third light emitting diode chip secured to the supporting surface, the third light emitting diode chip being configured to emit light having a third spectral distribution corresponding to red light.

15. The light emitting package as set forth in claim 14, wherein:
the third light emitting diode chip does not overlap the first light emitting diode chip.

16. A light emitting package comprising:
a support defining a support surface;
a first light emitting diode chip comprising a physically discrete component flip-chip bonded to the supporting surface and configured to be electrically energized to emit light having a first spectral distribution, the first light emitting diode chip comprising epitaxial layers and not including a lattice-matched substrate; and
a second light emitting diode chip secured on top of the first light emitting diode chip, the second light emitting diode chip comprising a physically discrete component configured to be electrically energized to emit light having a second spectral distribution different from the first spectral distribution.

17. The light emitting package as set forth in claim 16, wherein each of the first and second light emitting diode chips have operative input power greater than or about 1 watt.

18. The light emitting package as set forth in claim 16, wherein:
the first light emitting diode chip comprises (i) a plurality of group III-nitride epitaxial layers configured to be electrically energized to emit ultraviolet light and (ii) a phosphor containing material including a green phosphor that emits green light when excited by the ultraviolet radiation generated by the plurality of group III-nitride epitaxial layers; and
the second light emitting diode chip is configured to be electrically energized to emit blue light.

19. The light emitting package as set forth in claim 16, further comprising:
a third light emitting diode chip secured to the first light emitting diode chip, the third light emitting diode chip being configured to emit light having a third spectral distribution different from the first and second spectral distributions.

20. The light emitting package as set forth in claim 16, further comprising:
a third light emitting diode chip secured to the second light emitting diode chip, the third light emitting diode chip being configured to emit light having a third spectral distribution different from the first and second spectral distributions.

21. The light emitting package as set forth in claim 16, wherein the second light emitting diode chip has an area that is less than an area of the first light emitting diode chip.
